(19) United States
(12) Patent Application Publication
(10) Pub. No.: US 2019/0245033 A1
(43) Pub. Date: Aug. 8, 2019

(54) POWER SEMICONDUCTOR DEVICE

(71) Applicant: UBIQ Semiconductor Corp., Hsinchu County (TW)

(72) Inventor: Chin-Fu Chen, Hsinchu County (TW)

(73) Assignee: UBIQ Semiconductor Corp., Hsinchu County (TW)

(21) Appl. No.: 15/950,179

(22) Filed: Apr. 11, 2018

(30) Foreign Application Priority Data
Feb. 5, 2018 (TW) 107103941

(51) Int. Cl. H01L 29/06; H01L 29/423; H01L 29/40

(52) U.S. Cl. CPC H01L 29/0611; H01L 29/407; H01L 29/4236

(57) ABSTRACT

A power semiconductor device including a substrate having an active region and a terminal region is provided. The active region has a plurality of first trenches. The terminal region has a second trench. The first trenches are extended along a first direction and arranged along a second direction. The second trench is extended along the second direction. The first direction is intersected with the second direction. The second trench has a plurality of protruding portions respectively located between two adjacent first trenches.

### CROSS-REFERENCE TO RELATED APPLICATION

This application claims the priority benefit of Taiwan application serial no. 107103941, filed on Feb. 5, 2018. The entirety of the above-mentioned patent application is hereby incorporated by reference herein and made a part of this specification.

### BACKGROUND OF THE INVENTION

### Field of the Invention

The invention relates to a semiconductor device, and more particularly, to a power semiconductor device.

### Description of Related Art

The power semiconductor device is a semiconductor device widely used in an analog circuit. Since the power semiconductor device has a very low on-resistance and very fast switching speed, the power semiconductor device can be applied in a power switch circuit to make power management techniques more efficient.

With the advancement in technology, electronic devices are becoming compact. Since the size of electronic devices is getting smaller, maintaining a high breakdown voltage for the power semiconductor device is also becoming difficult. Therefore, how to increase the breakdown voltage of the power semiconductor device under a certain device size is an important topic.

### SUMMARY OF THE INVENTION

The invention provides a power semiconductor device that can uniform the distribution of a power line between an active region and a terminal region to increase the breakdown voltage of the element, so as to increase the reliability of the power semiconductor device.

The invention provides a power semiconductor device including a substrate having an active region and a terminal region. The active region has a plurality of first trenches. The terminal region has a second trench. The first trenches are extended along a first direction and arranged along a second direction. The second trench is extended along the second direction. The first direction is intersected with the second direction. The second trench has a plurality of protruding portions respectively located between two adjacent first trenches.

In an embodiment of the invention, each of the plurality of protruding portions has a central point located on a center line between the corresponding two adjacent first trenches.

In an embodiment of the invention, one of the first trenches has a first corner portion. Another first trench is adjacent to the one of the first trenches and has a second corner portion. A first distance is between the first corner portion and a corresponding central point. A second distance is between the second corner portion and the corresponding central point. The first distance is equal to the second distance.

In an embodiment of the invention, the second trench has a parallel portion and the plurality of protruding portions located on the first side of the parallel portion. A third distance is between the first side and the first trenches. The third distance is greater than the first distance.

In an embodiment of the invention, the protruding length of each of the plurality of protruding portions is less than the third distance.

In an embodiment of the invention, the plurality of protruding portions is protruded along a direction from the first side toward the active region.

In an embodiment of the invention, the plurality of protruding portions is extended from the top surface of the substrate into the substrate.

In an embodiment of the invention, the width of each of the plurality of protruding portions is less than the pitch between two adjacent first trenches.

In an embodiment of the invention, the contour of the plurality of protruding portions includes hill shape, rectangle, triangle, irregular shape, or a combination thereof.

In an embodiment of the invention, each of the first trenches includes a stripe portion and two extending portions. The stripe portion has two opposite ends along the first direction. The two extending portions are respectively disposed on the two ends of the stripe portion.

In an embodiment of the invention, the two extending portions cover two corners of the two ends of the stripe portion.

In an embodiment of the invention, the two extending portions and the two ends of the stripe portion are coplanar.

In an embodiment of the invention, the two extending portions completely cover the surface of the two ends of the stripe portion.

In an embodiment of the invention, the extending portions are separated from each other.

The invention provides a power semiconductor device including a substrate having an active region and a terminal region. The active region has a plurality of first trenches. The terminal region has a second trench. The first trenches are extended along a first direction and arranged along a second direction. The second trench is extended along the second direction. The first direction is intersected with the second direction. Each of the first trenches includes a stripe portion and two extending portions. The two extending portions are respectively disposed on two opposite ends of the stripe portion.

In an embodiment of the invention, the two extending portions cover two corners of the two ends of the stripe portion.

In an embodiment of the invention, the two extending portions and the two ends of the stripe portion are coplanar.

In an embodiment of the invention, the two extending portions completely cover the surface of the two ends of the stripe portion.

In an embodiment of the invention, the extending portions are separated from each other.

Based on the above, in the invention, the second trench of the terminal region has a plurality of protruding portions respectively located between two adjacent first trenches of the active region. Such configuration can adjust or reduce the distance between the first trenches of the active region and the second trench of the terminal region to uniform the distribution of the power line, so as to increase the breakdown voltage of the power semiconductor device and increase the reliability of the power semiconductor device.

Moreover, in the invention, two extending portions can also be disposed on two opposite ends of the strip portion of the first trenches in the active region to uniform the distribution of the power line between the active region and the terminal region, so as to increase the breakdown voltage of the power semiconductor device.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a power semiconductor device of the first embodiment of the invention.

FIG. 2A is an enlarged view of region A of FIG. 1.

FIG. 2B is an enlarged view of region B of FIG. 2A.

FIG. 2C is an enlarged three-dimensional view of region C of FIG. 2B.

FIG. 3A and FIG. 3B are respectively enlarged views of region A of FIG. 1.

FIG. 4 is a cross section of line I-I′ of FIG. 1.

FIG. 5 is a top view of a power semiconductor device of the second embodiment of the invention.

FIG. 6A to FIG. 6C are respectively enlarged views of region A′ of FIG. 2.

FIG. 7 is a top view of a power semiconductor device of the third embodiment of the invention.

### DESCRIPTION OF THE EMBODIMENTS

The invention is more comprehensively described with reference to the figures of the present embodiments. However, the invention can also be implemented in various different forms, and is not limited to the embodiments in the present specification. The thicknesses of the layers and regions in the figures are enlarged for clarity. The same or similar reference numerals represent the same or similar devices and are not repeated in the following paragraphs.

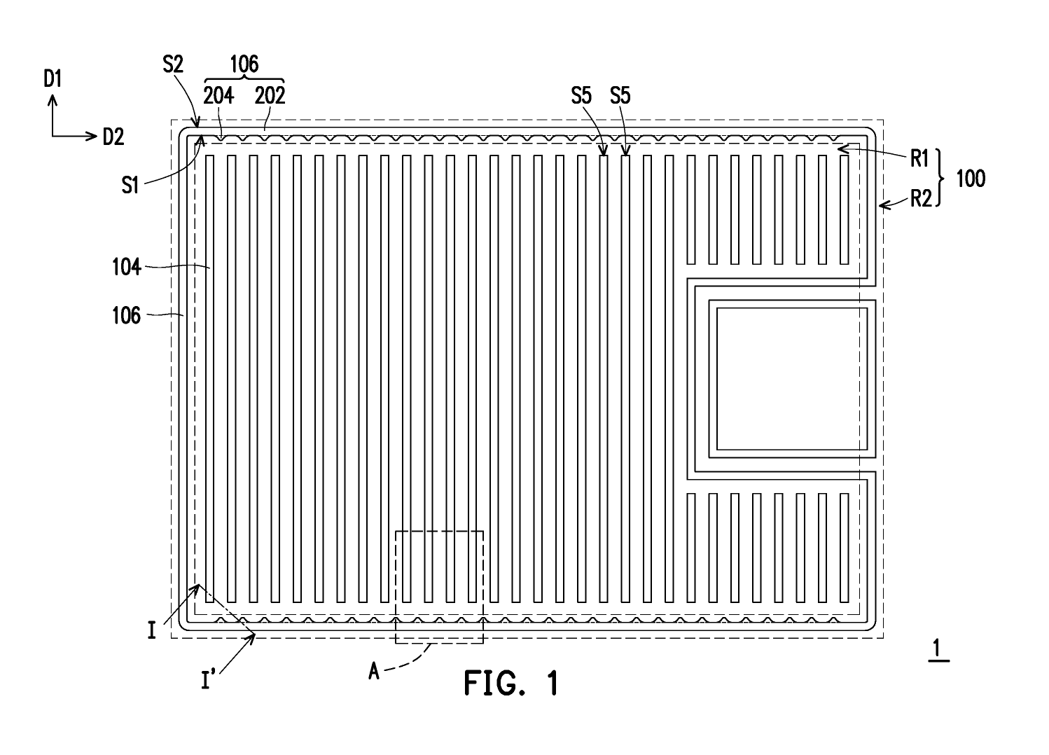

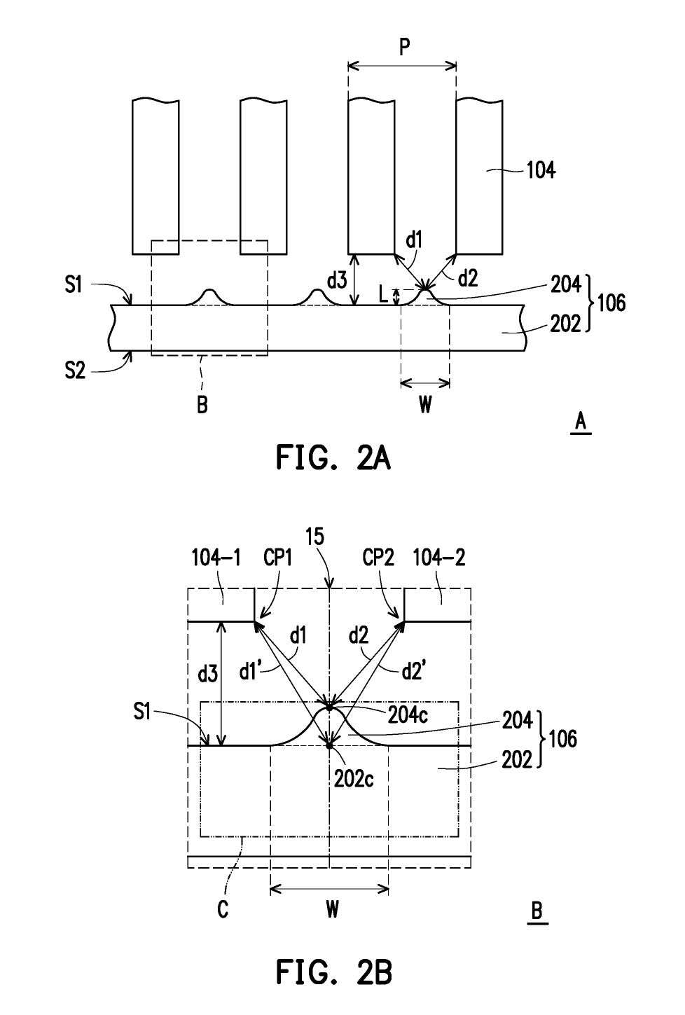

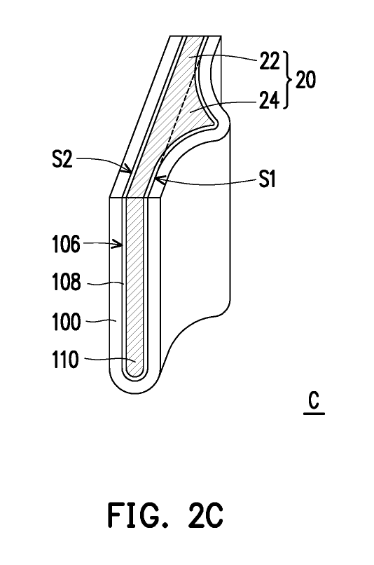

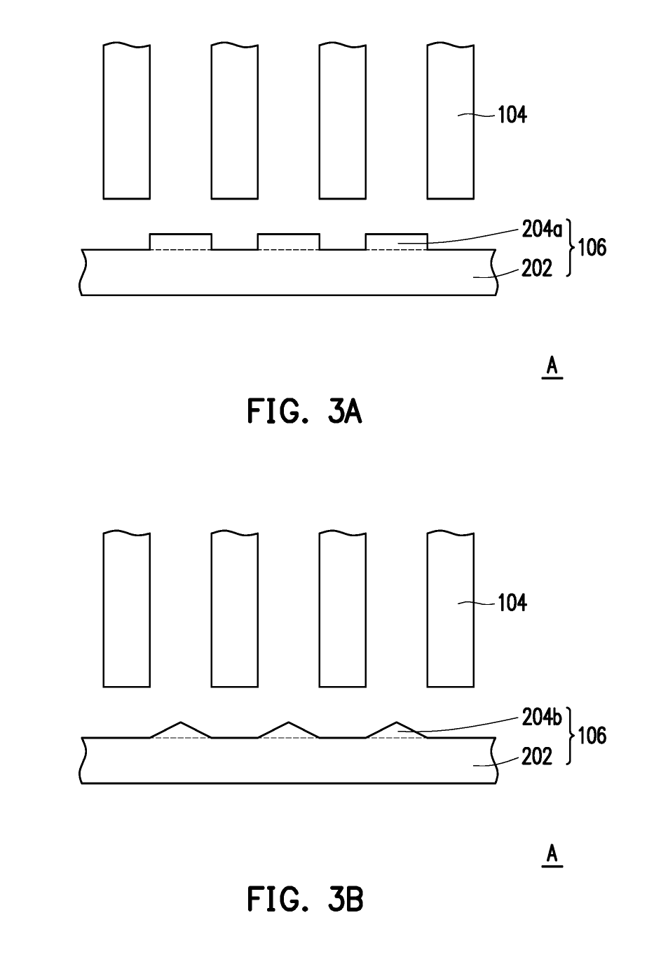

FIG. 1 is a top view of a power semiconductor device of the first embodiment of the invention. FIG. 2A is an enlarged view of region A of FIG. 1. FIG. 2B is an enlarged view of region B of FIG. 2A.

Referring to FIG. 1, a power semiconductor device 1 of the first embodiment of the invention includes a substrate 100 having an active region R1 and a terminal region R2. The terminal region R2 surrounds the active region R1 to prevent the occurance of a voltage collapse phenomenon. In an embodiment, the substrate 100 can be a semiconductor substrate, a semiconductor compound substrate, or a silicon substrate having an epitaxial layer thereon.

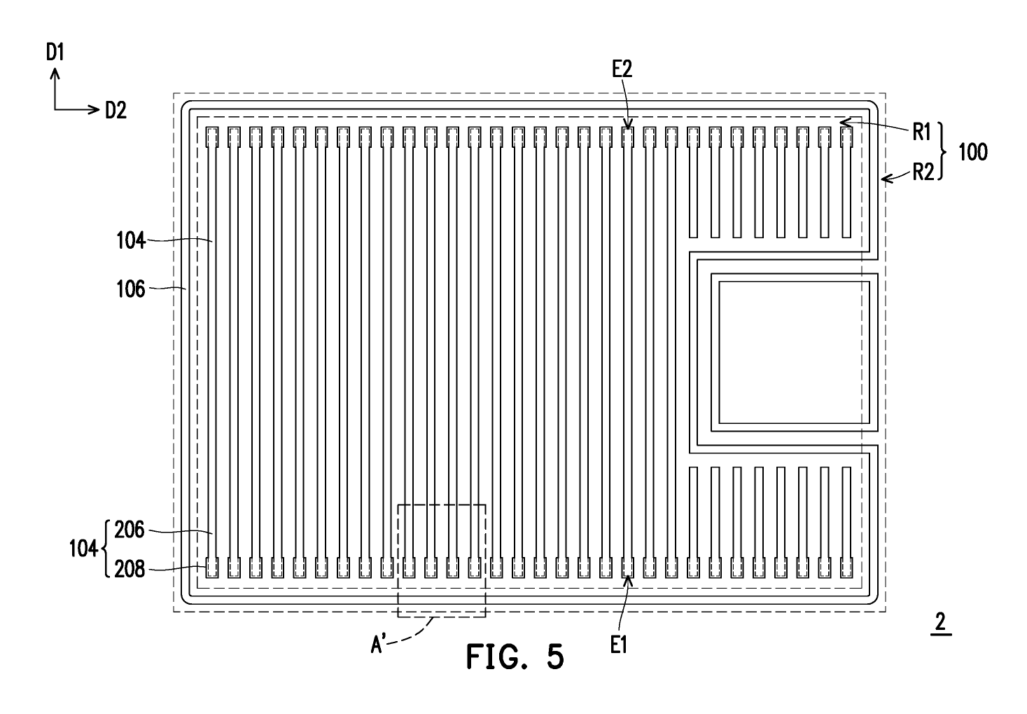

Specifically, the active region R1 has a plurality of first trenches 104. The first trenches 104 are disposed in the substrate 100 of the active region R1. The first trenches 104 are extended along a first direction D1 and arranged along a second direction D2. In an embodiment, the first trenches 104 are arranged in an equidistant manner and separated from one another. In an embodiment, terminal faces S5 of the first trenches 104 are substantially aligned. The terminal region R2 has a second trench 106. The second trench 106 is disposed in the substrate 100 of the terminal region R2. The second trench 106 is extended along the second direction D2 and surrounds the first trenches 104 in the active region R1 to form an enclosed annular trench. As shown in FIG. 1, the first trenches 104 and the second trench 106 are separated from each other and are not connected. The first direction D1 is intersected with the second direction D2. In an embodiment, the first direction D1 is perpendicular to the second direction D2. In the present embodiment, the first trenches 104 can be used as cell trenches to house a gate structure 10 (as shown in FIG. 4); and the second trench 106 can be used as a termination trench to house a terminal structure 20 (as shown in FIG. 4).

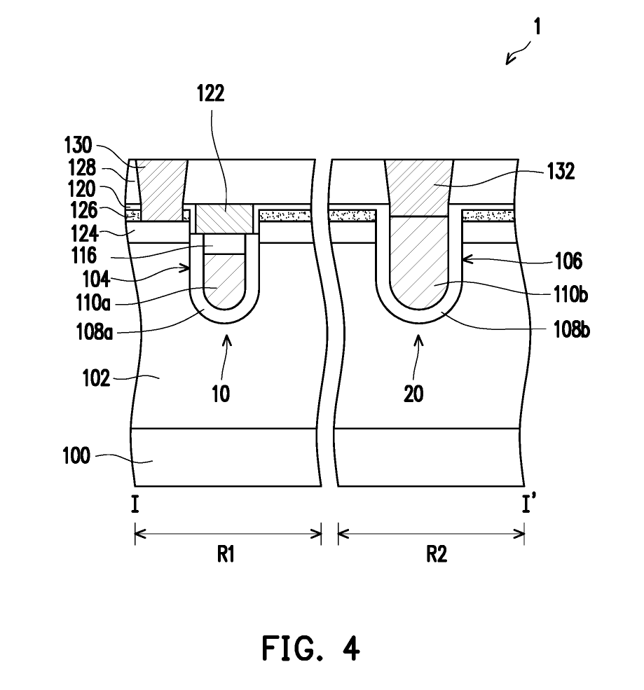

As shown in FIG. 1, the second trench 106 includes a parallel portion 202 and a plurality of protruding portions 204. Specifically, the parallel portion 202 is a strip groove parallelly disposed along the second direction D2 and having a first side S1 and a second side S2 opposite to each other. The first side S1 is adjacent to the active region R1 and can be regarded as the inner side; and the second side S2 is away from the active region R1 and can be regarded as the outer side. The plurality of protruding portions 204 is disposed on the first side S1 of the parallel portion 202. The protruding portions 204 are protruded along a direction from the first side S1 toward the active region R1. The second side S2 is a straight shape parallelly disposed along the second direction D2. In an embodiment, as shown in FIG. 2A, the contour of the protruding portions 204 can be hill-shaped. However, the invention is not limited thereto. In other embodiments, the contour of the protruding portions 204 can also be a rectangle (such as protruding portions 204a of FIG. 3A), a triangle (such as protruding portions 204b of FIG. 3B), an irregular shape, or a combination thereof.

Specifically, the protruding portions 204 are respectively located between two adjacent first trenches 104. In an embodiment, as shown in FIG. 2A, a width W of each of the protruding portions 204 is less than a pitch P between two adjacent first trenches 104. In an embodiment, as shown in FIG. 2B, the protruding portions 204 have a central point 204c located on a center line 15 between the two corresponding adjacent first trenches 104. As shown in FIG. 2B, a first trench 104-1 has as first corner portion CP1. A first trench 104-2 is adjacent to the first trench 104-1 and has a second corner portion CP2. A first distance d1 is between the first corner portion CP1 of the first trench 104-1 and the corresponding central point 204c. A second distance d2 is between the second corner portion CP2 of the first trench 104-2 and the corresponding central point 204c. In an embodiment, the first distance d1 is equal to the second distance d2. The minimum distance between the first side S1 of the second trench 106 and the first trenches 104 is a third distance d3. In an embodiment, the third distance d3 is greater than the first distance d1, and the third distance d3 is greater than the second distance d2. In an embodiment, a protruding length L of the protruding portions 204 is less than the third distance d3.

It should be mentioned that, as shown in FIG. 2B, in the present embodiment, the shape and size of the protruding portions 204 of the second trench 106 can be defined by a photomask to reduce a first distance d1′ between the first corner portion CP1 of the first trench 104-1 and an intersection 202c at the first side S1 (i.e., the intersection of the extending direction of the first side S1 of the second trench 106 and the center line 15) or to adjust the first distance d1′ to the first distance d1. Similarly, a distance d2′ between the second corner portion CP2 of the first trench 104-2 and the intersection 202c at the first side S1 can also be reduced or adjusted to the second distance d2. Therefore, a power line between the first trenches 104-1 and 104-2 of the active region R1 and the second trench 106 of the terminal region R2 can be uniformly distributed to effectively increase the breakdown voltage of the power semiconductor device 1, so as to increase the reliability of the power semiconductor device 1.

FIG. 2C is an enlarged three-dimensional view of region C of FIG. 2B.

Referring to both FIG. 1 and FIG. 2C, an insulating layer 108 and a conductive layer 110 can be filled in the second trench 106 of the terminal region R2 to form a terminal structure 20 in the substrate 100 of the terminal region R2. The insulating layer 108 conformally covers the inner surface of the second trench 106, and the conductive layer 110 completely fills the entire second trench 106 such that the insulating layer 108 is disposed between the conductive layer 110 and the substrate 100. Specifically, the terminal structure 20 includes a sheet structure 22 and a plurality of protruding structures 24 disposed on the first side S1. As shown in FIG. 1 and FIG. 2C, the protruding portions 204 of the second trench 106 are protruded along the direction from the first side S1 toward the active region R1 and extended from the top surface of the substrate 100 into the substrate 100. Therefore, the protruding structures 24 filled in the protruding portions 204 of the second trench 106 are also protruded along the direction from the first side S1 toward of the active region R1 and extended from the top surface of the substrate 100 into the substrate 100.

FIG. 4 is a cross section of line I-I′ of FIG. 1. In the following embodiments, the first conductivity type is N-type and the second conductivity type is P-type as an example. However, the invention is not limited thereto. Those having ordinary skill in the art should know that the first conductivity type can also be P-type and the second conductivity type can be N-type.

Referring to both FIG. 1 and FIG. 4, after the first trenches 104 and the second trench 106 are formed, the gate structure 10 is further formed in the first trenches 104 and the terminal structure 20 is formed in the second trench 106 to form the power semiconductor device 1 of the first embodiment of the invention. In an embodiment, the power semiconductor device 1 can be a trench metal-oxide-semiconductor field effect transistor, but the invention is not limited thereto.

Specifically, the power semiconductor device 1 includes a substrate 100, an epitaxial layer 102, a first conductive layer 110a, a second conductive layer 110b, a third conductive layer 122, a first insulation layer 108a, a second insulation layer 108b, and a third insulation layer 116.

As shown in FIG. 4, the substrate 100 has an active region R1 and a terminal region R2. In an embodiment, the substrate 100 can be a semiconductor substrate having a first conductivity type, such as an N-type heavily-doped silicon substrate. The epitaxial layer 102 is disposed on the substrate 100, and the epitaxial layer 102 has the first trenches 104 located in the active region R1 and the second trench 106 located in the terminal region R2. In an embodiment, the epitaxial layer 102 is an epitaxial layer having a first conductivity type, such as an N-type lightly-doped epitaxial layer, and the forming method thereof includes performing a selective epitaxy growth (SEG) process.

The first conductive layer 110a is disposed in the first trenches 104. The second conductive layer 110b is disposed in the second trench 106. The third conductive layer 122 is disposed in the first trenches 104 and located on the first conductive layer 110a. In an embodiment, the material of the first conductive layer 110a, the second conductive layer 110b, and the third conductive layer 122 respectively includes doped polysilicon, and the forming method thereof includes performing a chemical vapor deposition process.

The first insulation layer 108a is disposed between the first conductive layer 110a and the epitaxial layer 102. The second insulation layer 108b is disposed between the second conductive layer 110b and the epitaxial layer 102. The third insulation layer 116 is disposed between the first conductive layer 110a and the third conductive layer 122. In an embodiment, the material of the first insulation layer 108a, the second insulation layer 108b, and the third insulation layer 116 respectively includes silicon oxide, and the forming method thereof includes performing thermal oxidation or a chemical vapor deposition process. Moreover, the top surface of the first conductive layer 110a is lower than the top surface of the second conductive layer 110b. In an embodiment, since the line I-I′ crosses the protruding portions 204 of the second trench 106, in the cross section of line I-I′, the width of the second trench 106 (or the second conductive layer 110b) is greater than the width of the first trenches 104 (or the first conductive layer 110a).

In an embodiment, the width of the third insulation layer is the same as the width of the first conductive layer 110a. In an embodiment, the third insulation layer 116 is in contact with the first insulation layer 108a to electrically isolate the first conductive layer 110a and the third conductive layer 122. In an embodiment, as shown in FIG. 4, the top surface of the third insulation layer 116 and the top surface of the first insulation layer 108a are substantially level. However, the invention is not limited thereto, and in other embodiments, the top surface of the third insulation layer 116 is lower than the top surface of the first insulation layer 108a.

In an embodiment, the power semiconductor device 1 further includes a dielectric layer 120, a body layer 124, and a doped region 126. The body layer 124 is disposed in the epitaxial layer 102 of the active region R1 and the terminal region R2 and surrounds the first trenches 104 and the second trench 106. In an embodiment, the body layer 124 is a body layer having a second conductivity type, such as a P-type body layer, and the forming method thereof includes performing an ion implantation process. The doped region 126 is disposed in the body layer 124 of the active region R1 and the terminal region R2 and surrounds the upper portions of the first trenches 104 and the second trench 106. In an embodiment, the doped region 126 is a doped region 126 having a first conductivity type, such as an N-type heavily-doped region, and the forming method thereof includes performing an ion implantation process. The dielectric layer 120 surrounds the sidewall of the third conductive layer 122 and is extended to cover the top surface of the doped region 126 of the active region R1 and the terminal region R2. In an embodiment, the material of the dielectric layer 120 includes silicon oxide, and the forming method thereof includes performing thermal oxidation. In an embodiment, the bottom layer of the body layer 124 is lower than the top surface of the third insulation layer 116.

In an embodiment, the power semiconductor device 1 further includes a dielectric layer 128, a first contact 130, and a second contact 132. The dielectric layer 128 is disposed on the epitaxial layer 102 of the active region R1 and the terminal region R2. In an embodiment, the material of the dielectric layer 128 includes silicon oxide, borophosphosilicate glass (BPSG), phosphosilicate glass (PSG), fluorosilicate glass (FSG), or undoped silicon glass (USG), and the forming method thereof includes performing a chemical vapor deposition process. The first contact 130 passes through the dielectric layer 128 and the dielectric layer 120 to be electrically connected to the doped region 126. The second contact 132 passes through the dielectric layer 128 and is electrically connected to the second conductive layer 110b. In an embodiment, the material of the first contact 130 and the second contact 132 includes a conductive material, and can be a metal, such as aluminum, and the forming method thereof includes performing a chemical vapor deposition process.

In the power semiconductor device 1 of the present embodiment, the third conductive layer 122 can be used as a gate, the dielectric layer 120 can be used as a gate dielectric layer, and the first conductive layer 110a can be used as a shield electrode to form the gate structure 10. The substrate 100 can be used as a drain, and the doped region 126 can be used as a source. In an embodiment, as shown in FIG. 4, the combination of the third insulation layer 116 and a portion of the first insulation layer 108a can be used as an inter-gate insulation layer between a gate (such as the third conductive layer 122) and a shield electrode (such as the first conductive layer 110a).

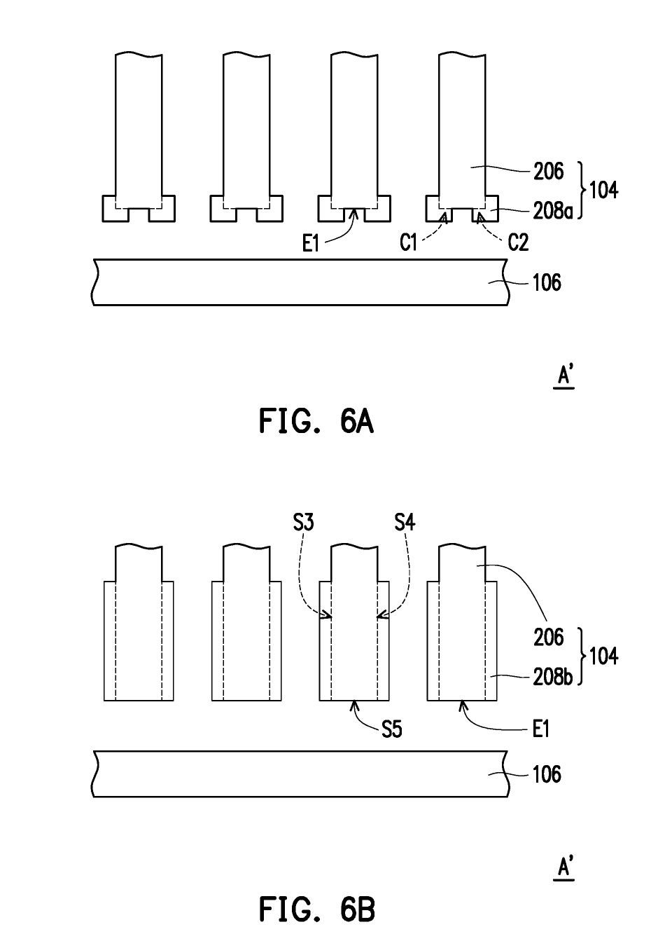

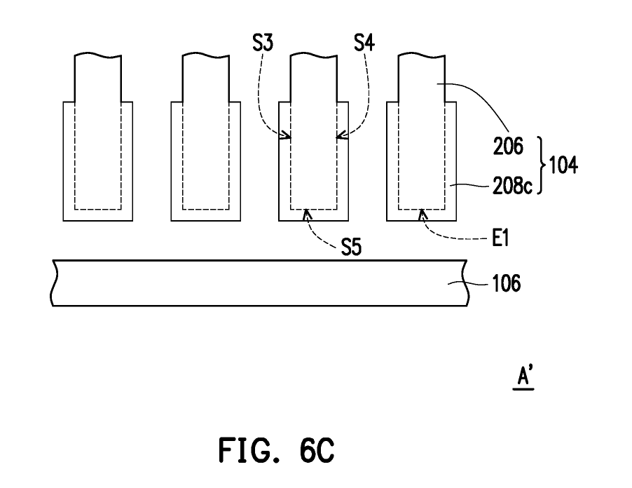

FIG. 5 is a top view of a power semiconductor device of the second embodiment of the invention. FIG. 6A to FIG. 6C are respectively enlarged views of region A′ of FIG. 2.

Referring to FIG. 5, basically, a power semiconductor device 2 of the second embodiment of the invention is similar to the power semiconductor device 1 of the first embodiment. The difference between the two is that the first trenches 104 of the power semiconductor device 2 of the second embodiment include a strip portion 206 and two extending portions 208. The strip portion 206 has two opposite ends E1 and E2 along the first direction D1. The two extending portions 208 are respectively disposed on the two ends E1 and E2 of the strip portion 206. In an embodiment, the extending portions 208 are separated from each other and not connected. Moreover, the second trench 106 of the power semiconductor device 2 of the second embodiment does not include a plurality of protruding portions.

In an embodiment, as shown in FIG. 6A, the two extending portions 208a cover two corners C1 and C2 of the two ends E1 and E2 of the strip portion 206. In another embodiment, as shown in FIG. 6B, the extending portions 208b cover two sidewalls S3 and S4 of the two ends E1 and E2 of the strip portion 206 and do not cover the terminals surfaces S5 of the two ends E1 and E2. In other words, the terminal face S5 of the two ends E1 and E2 of the strip portion 206 is exposed to the two extending portions 208b, and the two extending portions 208b and the terminal face S5 of the two ends E1 and E2 of the strip portion 206 are coplanar. In other embodiments, as shown in FIG. 6C, the two extending portions 208c completely cover the surface of the two ends E1 and E2 of the strip portion 206. In other words, the two extending portions 208c cover the two sidewalls S3 and S4 of the two ends E1 and E2 of the strip portion 206 and the terminal face S5 of the two ends E1 and E2.

It should be mentioned that, in the present embodiment, the shape and size of the extending portions 208 of the first trenches 104 can be defined via a photomask such that the power line between the first trenches 104 of the active region R1 and the second trench 106 of the terminal region R2 is uniformly distributed to increase the breakdown voltage of the power semiconductor device 2 and increase the reliability of the power semiconductor device 2.

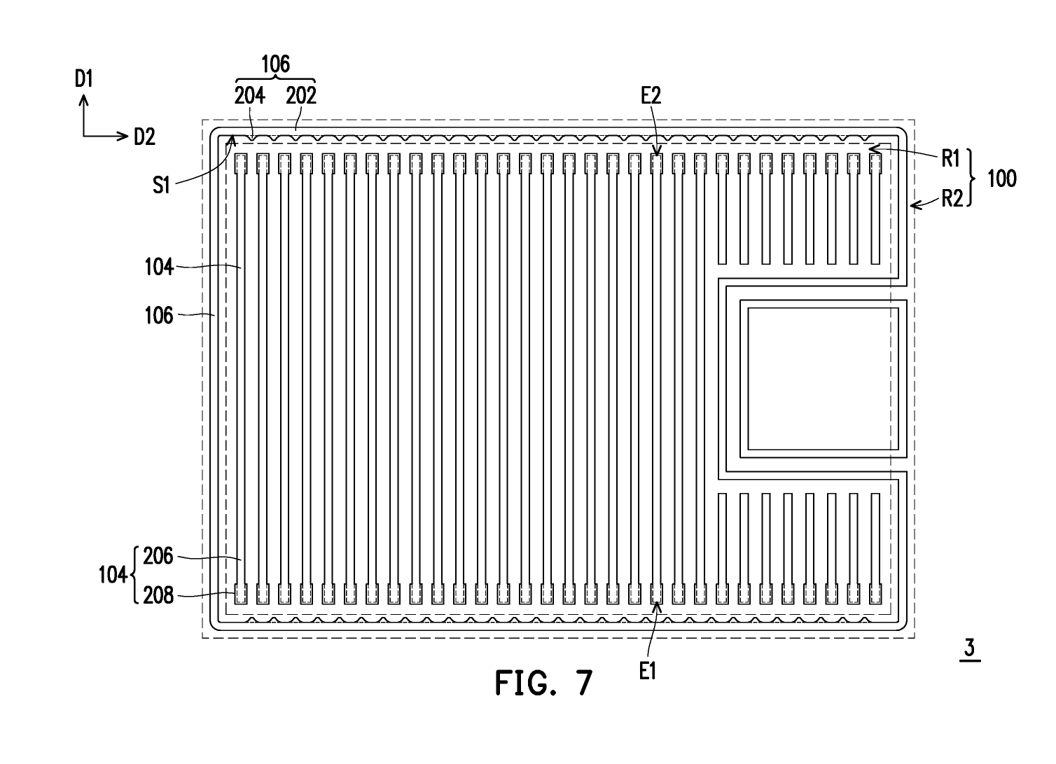

FIG. 7 is a top view of a power semiconductor device of the third embodiment of the invention.

Referring to FIG. 7, basically, a power semiconductor device 3 of the third embodiment of the invention combines the protruding portions 204 of the power semiconductor device 1 of the first embodiment and the extending portions 208 of the power semiconductor device 2 of the second embodiment, such that the power line between the first trenches 104 of the active region R1 and the second trench 106 of the terminal region R2 is uniformly distributed to increase the breakdown voltage of the power semiconductor device 3 and increase the reliability of the power semiconductor device 3. In other words, the power semiconductor device 3 not only has the protruding portions 204 on the first side S1 of the parallel portion 202 of the second trench 106, but also has the two extending portions 208 on the two ends E1 and E2 of the strip portion 206 of the first trenches 104.

Based on the above, in the invention, the second trench of the terminal region has a plurality of protruding portions respectively located between two adjacent first trenches of the active region. Such configuration can adjust or reduce the distance between the first trenches of the active region and the second trench of the terminal region to uniform the distribution of the power line so as to increase the breakdown voltage of the power semiconductor device and increase the reliability of the power semiconductor device.

Moreover, in the invention, two extending portions can also be disposed on two opposite ends of the strip portion of the first trenches in the active region to uniform the distribution of the power line between the active region and the terminal region so as to increase the breakdown voltage of the power semiconductor device.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

1. A power semiconductor device, comprising:
a substrate having an active region and a terminal region, wherein the active region has a plurality of first trenches, the terminal region has a second trench, the first trenches are extended along a first direction and arranged along a second direction, the second trench is extended along the second direction, and the first direction and the second direction are intersected,
wherein the second trench has a parallel portion and a plurality of protruding portions, the parallel portion has a first side and a second side opposite to each other, the first side is adjacent to the active region, the protruding portions are located on the first side of the parallel portion and respectively located between two adjacent first trenches, and the second side of the parallel portion is a straight shape parallelly disposed along the second direction.

2. The power semiconductor device of claim 1, wherein each of the protruding portions has a central point located on a center line between the corresponding two adjacent first trenches.

3. The power semiconductor device of claim 2, wherein
one of the first trenches has a first corner portion,
another of the first trenches is adjacent to the one of the first trenches and has a second corner portion,
a first distance is between the first corner portion and a corresponding central point, a second distance is between the second corner portion and the corresponding central point, and the first distance is equal to the second distance.

4. The power semiconductor device of claim 3, wherein a third distance is between the first side and the first trenches, and the third distance is greater than the first distance.

5. The power semiconductor device of claim 4, wherein a protruding length of each of the plurality of protruding portions is less than the third distance.

6. The power semiconductor device of claim 4, wherein the protruding portions is protruded along a direction from the first side toward the active region.

7. The power semiconductor device of claim 1, wherein the plurality of protruding portions is extended from a top surface of the substrate into the substrate.

8. The power semiconductor device of claim 1, wherein a width of each of the plurality of protruding portions is less than a pitch between two adjacent first trenches.

9. The power semiconductor device of claim 1, wherein a contour of the plurality of protruding portions comprises a hill shape, a rectangle, a triangle, an irregular shape, or a combination thereof.

10. The power semiconductor device of claim 1, wherein each of the first trenches comprises:
a stripe portion having two opposite ends along the first direction; and
two extending portions respectively disposed on the two ends of the stripe portion.

11. The power semiconductor device of claim 10, wherein the two extending portions cover two corners of the two ends of the stripe portion.

12. The power semiconductor device of claim 10, wherein the two extending portions and the two ends of the stripe portion are coplanar.

13. The power semiconductor device of claim 10, wherein the two extending portions completely cover a surface of the two ends of the stripe portion.

14. The power semiconductor device of claim 10, wherein the extending portions are separated from each other.

15. (canceled)

16. (canceled)

17. (canceled)

18. (canceled)

19. (canceled)
